(19) United States
(12) Patent Application Publication
(10) Pub. No.: US 2009/0075213 A1
(43) Pub. Date: Mar. 19, 2009

(54) Method of forming an auto-calibration label using a laser

(75) Inventor: Andrew J. Edelbrock, Granger, IN (US)

Correspondence Address: NIXON PEABODY LLP, 161 N. CLARK STREET, 48TH FLOOR, CHICAGO, IL, 60601, US

(73) Assignee: Bayer Healthcare Inc., Tarrytown, NY (US)

(21) Appl. No.: 11/918,826

(22) PCT Filed: Apr. 18, 2006
(86) PCT No.: PCT/US2006/014821

§ 371 Date: Oct. 18, 2007

Related U.S. Application Data
(60) Provisional application No. 60/672,790, filed on Apr. 19, 2005.
(60) Provisional application No. 60/678,084, filed on May 5, 2005.

(51) Int. Cl. H01L 21/70

(52) U.S. Cl. 430/319; 430/311

(57) ABSTRACT

An auto-calibration circuit or label (20) is formed to be used with an instrument (10). A structure is provided that includes an electrically conductive layer. A pattern is created with the electrically conductive layer using a laser to form an auto-calibration circuit or label. The pattern is adapted to be utilized by the instrument to auto-calibrate. The pattern may be adapted to be utilized for a first instrument and a second instrument to auto-calibrate in which the first and second instruments are different.

### FIELD OF THE INVENTION

The present invention generally relates to methods of forming an auto-calibration circuit or label. The auto-calibration circuits or labels are used in automatically calibrating instruments or meters that determine the concentration of an analyte (e.g., glucose) in a fluid.

### BACKGROUND OF THE INVENTION

The quantitative determination of analytes in body fluids is of great importance in the diagnoses and maintenance of certain physiological abnormalities. For example, lactate, cholesterol and bilirubin should be monitored in certain individuals. In particular, it is important that diabetic individuals frequently check the glucose level in their body fluids to regulate the glucose intake in their diets. The results of such tests can be used to determine what, if any, insulin or other medication needs to be administered. In one type of blood-glucose testing system, sensors are used to test a sample of blood.

A test sensor contains biosensing or reagent material that reacts with blood glucose. The testing end of the sensor is adapted to be placed into the fluid being tested, for example, blood that has accumulated on a person's finger after the finger has been pricked. The fluid is drawn into a capillary channel that extends in the sensor from the testing end to the reagent material by capillary action so that a sufficient amount of fluid to be tested is drawn into the sensor. The fluid then chemically reacts with the reagent material in the sensor resulting in an electrical signal indicative of the glucose level in the fluid being tested. This signal is supplied to the meter via contact areas located near the rear or contact end of the sensor and becomes the measured output.

Diagnostic systems, such as blood-glucose testing systems, typically calculate the actual glucose value based on a measured output and the known reactivity of the reagent-sensing element (test sensor) used to perform the test. The reactivity or lot-calibration information of the test-sensor may be given to the user in several forms including a number or character that they enter into the instrument. One prior art method included using an element that is similar to a test sensor, but which was capable of being recognized as a calibration element by the instrument. The test element's information is read by the instrument or a memory element that is plugged into the instrument's microprocessor board for directly reading the test element.

These methods suffer from the disadvantage of relying on the user to enter the calibration information, which some users may not do. In this event, the test sensor may use the wrong calibration information and thus return an erroneous result. Improved systems use an auto-calibration label that is associated with the sensor package. The auto-calibration circuit or label is read automatically when the sensor package is placed in the meter and requires no user intervention.

One auto-calibration circuit or label used in the past was created using standard screen-printing technology. This technology, however, is limited to certain lines sizes and spaces. When the auto-calibration circuit or label needs to include a number of auto-calibration pads in a limited space (e.g., a set of auto-calibration pads for a first instrument and a second set of auto-calibration pads for a second instrument), the screen-printing method for forming the label may need to include three separate print passes. Besides being more complicated, using a three print standard screen-printing method adds additional tolerances.

As new and improved instruments or meters are being developed and used by consumers, the older instruments or meters will still be used for an unknown period of time. If calibration codes adapted for characteristics of the new and improved instruments are used in older meters, test results may be inaccurate, which is undesirable. It would be desirable to provide a method of forming the auto-calibration circuit or label that provides the lot-calibration information of the test sensor in an easy and reliable manner.

### SUMMARY OF THE INVENTION

According to one method, an auto-calibration circuit or label is formed to be used with an instrument. A structure is provided that includes an electrically conductive layer. A pattern is created with the electrically conductive layer using a laser to form an auto-calibration circuit or label. The pattern is adapted to be utilized by the instrument to auto-calibrate.

According to another method, an auto-calibration circuit or label is formed to be used with a first instrument and a second instrument. The first instrument is different from the second instrument. A structure is provided that includes an electrically conductive layer. A pattern is created with the electrically conductive layer using a laser to form an auto-calibration circuit or label. The pattern is adapted to be utilized by the first instrument to auto-calibrate and is adapted to be utilized by the second instrument to auto-calibrate.

According to a further method, a sensor package is formed that is adapted to be used with at least one instrument in determining an analyte concentration in a fluid sample. A structure is provided that includes an electrically conductive layer. A pattern is created with the electrically conductive layer using a laser to form an auto-calibration circuit or label. The pattern is adapted to be utilized by at least one instrument to auto-calibrate. The auto-calibration circuit or label is attached to a surface of a sensor-package base. At least one test sensor is provided that is adapted to receive the fluid sample and is operable with the at least one instrument.

According to yet another method, a sensor package is formed that is adapted to be used with at least one instrument in determining an analyte concentration in a fluid sample. A sensor-package base is provided having a surface. At least a portion of the surface of the sensor-package base includes an electrically conductive layer. A pattern is created with the electrically conductive layer using a laser to form an auto-calibration circuit or label. The pattern is adapted to be utilized by at least one instrument to auto-calibrate. At least one test sensor is provided that is adapted to receive the fluid sample and is operable with the at least one instrument.

### BRIEF DESCRIPTION OF THE DRAWINGS

FIG. 1 shows a sensing instrument according to one embodiment.

FIG. 2 shows the interior of the sensing instrument of FIG. 1.

FIG. 3 shows a sensor package according to one embodiment for use with the sensing instrument of FIG. 2.

FIG. 4 shows an auto-calibration circuit or label formed by one method of the present invention.

FIG. 5 shows the auto-calibration circuit or label of FIG. 4 according to one pattern.

FIG. 6 shows an auto-calibration circuit or label formed by another method of the present invention.

FIG. 7 shows an auto-calibration circuit or label of FIG. 6 according to one pattern.

FIG. 8 shows an auto-calibration circuit or label formed by another method of the invention.

### DETAILED DESCRIPTION OF ILLUSTRATED EMBODIMENTS

An instrument or meter in one embodiment uses a test sensor adapted to receive a fluid sample to be analyzed, and a processor adapted to perform a predefined test sequence for measuring a predefined parameter value. A memory is coupled to the processor for storing predefined parameter data values. Calibration information associated with the test sensor may be read by the processor before the fluid sample to be measured is received. Calibration information may be read by the processor after the fluid sample to be measured is received, but not after the concentration of the analyte has been determined. Calibration information is used in measuring the predefined parameter data value to compensate for different characteristics of test sensors, which will vary on a batch-to-batch basis. Variations of this process will be apparent to those of ordinary skill in the art from the teachings disclosed herein, including but not limited to, the drawings.

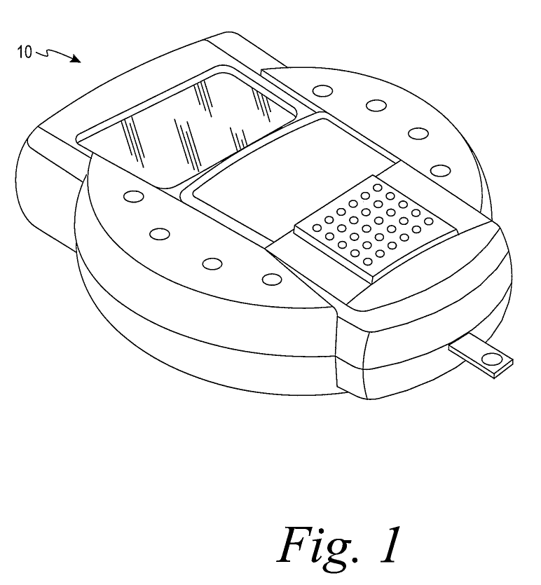

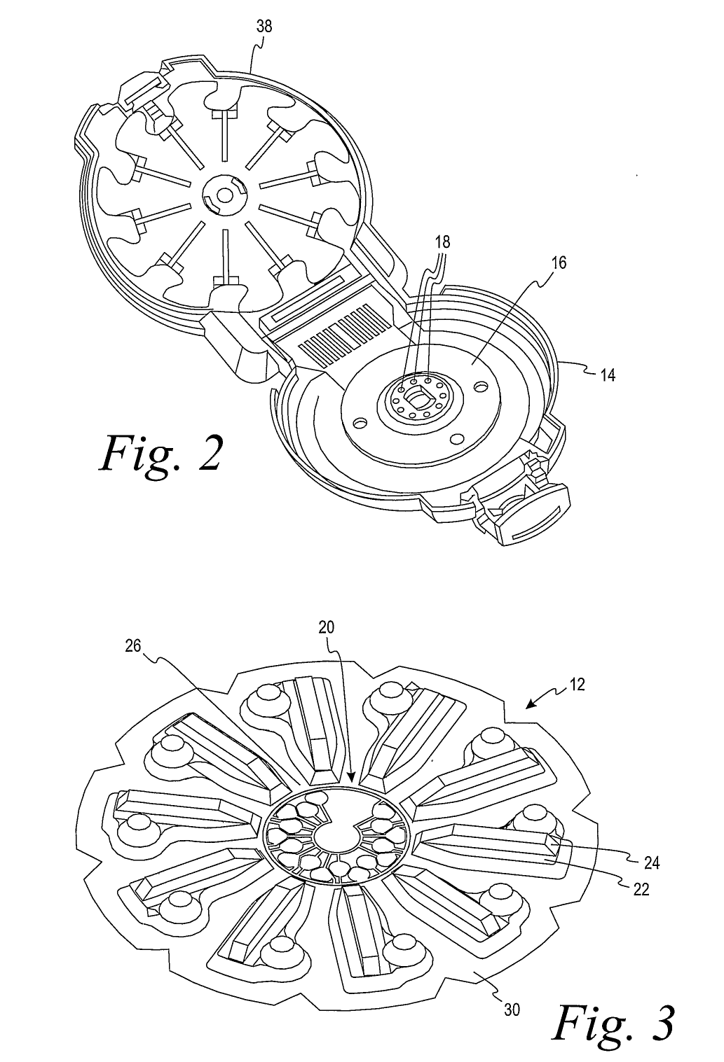

Referring now to FIGS. 1-3, an instrument or meter 10 is illustrated. In FIG. 2, the inside of the instrument 10 is shown in the absence of a sensor package. One example of a sensor package (sensor package 12) is separately illustrated in FIG. 3. Referring back to FIG. 2, a base member 14 of the instrument 10 supports an auto-calibration plate 16 and a predetermined number of auto-calibration pins 18. As shown in FIG. 2, for example, the instrument 10 includes ten auto-calibration pins 18. It is contemplated that the number of auto-calibration pins may vary in number and shape from that shown in FIG. 2. The auto-calibration pins 18 are connected for engagement with the sensor package 12.

The sensor package 12 of FIG. 3 includes an auto-calibration circuit or label 20, a plurality of test sensors 22, and a sensor-package base 26. The plurality of test sensors 22 is used to determine concentrations of analytes. Analytes that may be measured include glucose, lipid profiles (e.g., cholesterol, triglycerides, LDL and HDL), microalbumin, hemoglobin A_{1C}, fructose, lactate, or bilirubin. It is contemplated that other analyte concentrations may be determined. The analytes may be in, for example, a whole blood sample, a blood serum sample, a blood plasma sample, other body fluids like ISF (interstitial fluid) and urine, and non-body fluids. As used within this application, the term “concentration” refers to an analyte concentration, activity (e.g., enzymes and electrolytes), titers (e.g., antibodies), or any other measure concentration used to measure the desired analyte.

In one embodiment, the plurality of test sensors 22 includes an appropriately selected enzyme to react with the desired analyte or analytes to be tested. An enzyme that may be used to react with glucose is glucose oxidase. It is contemplated that other enzymes may be used such as glucose dehydrogenase. An example of a test sensor is disclosed in U.S. Pat. No. 6,531,040 assigned to Bayer Corporation. It is contemplated that other test sensors may be used.

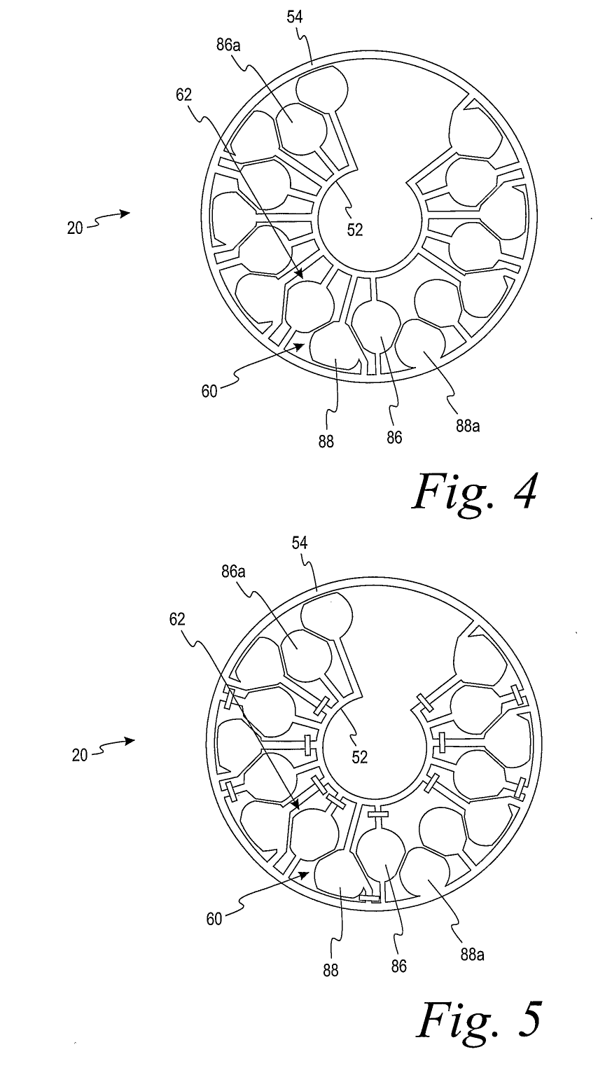

Calibration information or codes assigned for use in the clinical value computations to compensate for manufacturing variations between sensor lots are encoded on the auto-calibration circuit or label 20. The auto-calibration circuit or label 20 is used to automate the process of transferring calibration information (e.g., the lot specific reagent calibration information for the plurality of test sensors 22) such that the sensors 22 may be used with at least one instrument or meter. In one embodiment, the auto-calibration circuit or label 20 is adapted to be used with different instruments or meters. The auto-calibration pins 18 electrically couple with the auto-calibration circuit or label 20 when a cover 38 of the instrument 10 is closed and the circuit or label 20 is present. The auto-calibration circuit or label 20 will be discussed in detail in connection with FIG. 4.

According to one method, an analyte concentration of a fluid sample is determined using electrical current readings and at least one equation. In this method, equation constants are identified using the calibration information or codes from the auto-calibration circuit or label 20. These constants may be identified by (a) using an algorithm to calculate the equation constants or (b) retrieving the equation constants from a lookup table for a particular predefined calibration code that is read from the auto-calibration circuit or label 20. The auto-calibration circuit or label 20 may be implemented by digital or analog techniques. In a digital implementation, the instrument assists in determining whether there is conductance along selected locations to determine the calibration information. In an analog implementation, the instrument assists in measuring the resistance along selected locations to determine the calibration information.

Referring back to FIG. 3, the plurality of test sensors 22 is arranged around the auto-calibration circuit or label 20 and extends radially from the area containing the circuit or label 20. The plurality of sensors 22 of FIG. 3 is stored in individual cavities or blisters 24 and read by associated sensor electronic circuitry before one of the plurality of test sensors 22 is used. The plurality of sensor cavities or blisters 24 extends toward a peripheral edge of the sensor package 12. In this embodiment, each sensor cavity 24 accommodates one of the plurality of test sensors 22.

The sensor package 12 of FIG. 3 is generally circular in shape with the sensor cavities 24 extending from near the outer peripheral edge toward and spaced apart from the center of the sensor package 12. It is contemplated, however, that the sensor package may be of different shapes then depicted in FIG. 3. For example, the sensor package may be a square, rectangle, other polygonal shapes, or non-polygonal shapes including oval.

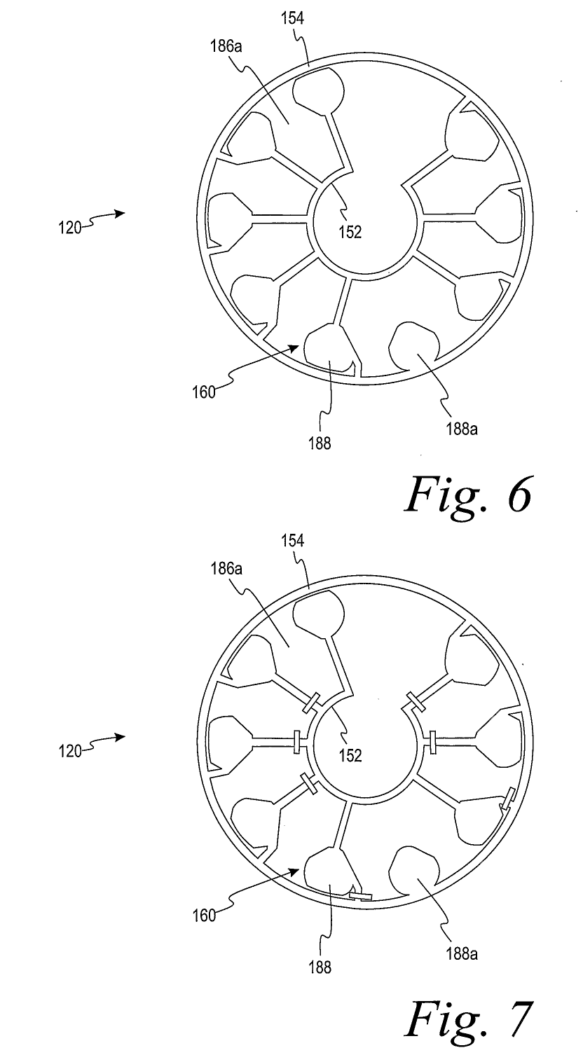

With reference to FIG. 4, the auto-calibration circuit or label 20 in this embodiment is adapted to be used with (a) the instrument or meter 10, (b) a second instrument or meter (not shown) being distinct or different from the instrument 10, and (c) the plurality of sensors 22 operable with both the instrument 10 and the second instrument. Thus, in this embodiment, the auto-calibration circuit or label 20 may be considered as “backwards” compatible because it is adapted to be used with the second instrument (i.e., a new instrument) and the first instrument (i.e., an older instrument). The auto-calibration circuit or label may be used to work with two older instruments or two newer instruments. To reduce or avoid manufacturing modifications, it is desirable for a “backwards” compatible auto-calibration label not to increase the size of the label or decrease the size of the electrical contact areas. In another embodiment that will be discussed below in connection with FIGS. 6 and 7, an auto-calibration circuit or label is adapted to be used with one instrument.

According to one embodiment, the sensor package contains a plurality of sensors operable with at least one instrument (e.g., sensor package 12 containing a plurality of sensors 22 operable with the instrument 10 and the second instrument). When the plurality of sensors 22 has essentially the same calibration characteristics, calibrating the instrument 10 for one of the sensors 22 is effective to calibrate the instrument 10 for each of the plurality of sensors 22 in that particular package 12.

The auto-calibration circuit or label 20 of FIG. 4 includes an inner ring 52, an outer ring 54, a plurality of electrical connections 60, and a plurality of electrical connections 62 distinct from the plurality of electrical connections 60. For some applications, the inner ring 52 represents logical 0s and the outer ring 54 represents logical 1s. It is contemplated that the inner ring or the outer ring may not be continuous. For example, the inner ring 52 is not continuous because it does not extend to form a complete circle. The outer ring 54, on the other hand, is continuous. The inner ring and the outer ring may both be continuous and in another embodiment the inner ring and the outer ring are not continuous. It is contemplated that the inner ring and outer rings may be shapes other than circular. Thus, the term “ring” as used herein includes non-continuous strictures and shapes other than circular.

The plurality of electrical connections 60 includes a plurality of outer contact areas 88 (e.g., contact pads). The plurality of outer contact areas 88 is radially positioned around the circumference of the auto-calibration circuit or label 20. The plurality of electrical connections 62 includes a plurality of inner contact areas 86. The inner contact areas 86 are positioned closed to the center of the circuit or label 20 than the outer contact areas 88. It is contemplated that the plurality of outer contact areas and the inner contact areas may be located in different positions than depicted in FIG. 4.

The plurality of electrical connections 62 is distinct from the plurality of electrical connections 60. It will be understood, however, that use of the term “distinct” in this context may only mean that the encoded information is distinct, but the decoded information is essentially the same. For example, the instrument 10 may have essentially the same calibration characteristics, but the contacts, e.g., pins 18, to couple with the encoded-calibration information are located in different places for each instrument. Accordingly, the encoded-calibration information of the first and second instruments corresponding to each instrument is distinct because the encoded information must be arranged to couple with the appropriate instrument.

In the embodiment depicted in FIG. 4, the plurality of electrical connections 60 is adapted to be routed directly from each of the plurality of outer contact areas 88 to a respective first common connection (e.g., inner ring 52) or a second common connection (e.g., outer ring 54). Thus, the electrical connections of the plurality of outer contact areas 88 are not routed through any of the inner contact areas 86. By having such an arrangement, additional independent encoded-calibration information may be obtained using the same total number of inner and outer contact areas 86, 88 without increasing the size of the auto-calibration circuit or label 20. Additionally, potential undesirable electrical connections may occur if the electrical connections of outer contact areas (e.g., outer pads) are routed through inner contact areas (e.g., inner pads). It is contemplated in another embodiment, however, that the outer contact areas may be routed through inner contact areas.

The plurality of electrical connections 60 is adapted to be utilized by the first instrument to auto-calibrate. The plurality of electrical connections 62, on the other hand, is adapted to be utilized by the second instrument to auto-calibrate. Thus, the positioning of the outer contact areas 88 and the inner contact areas 86 permits the auto-calibration circuit or label 20 to be read by instruments or meters that are capable of contacting either the plurality of outer contact areas 88 or the plurality of inner contact areas 86.

The information from the plurality of electrical connections 60 corresponds to the plurality of test sensors 22. The information obtained from the plurality of electrical connections 62 also corresponds to the plurality of test sensors 22.

According to one embodiment, substantially all of the plurality of outer contact areas 88 are initially electrically connected to the first common connection (e.g., inner ring 52) and the second common connection (e.g., outer ring 54). To program the auto-calibration label, substantially all of the outer contact areas 88 in this embodiment will only be connected to one of the inner or outer rings 52, 54. Similarly, substantially all of the plurality of inner contact areas 86 are initially electrically connected to the first common connection (e.g., inner ring 52) and the second common connection (e.g., outer ring 54). To program the auto-calibration circuit or label, substantially all of the inner contact areas 86 in this embodiment will only be connected to one of the inner or outer rings 52, 54.

FIG. 4 does not depict a specific pattern, but rather shows a number of the potential connections of the plurality of outer and inner contact areas to the first and second common connections. One example of a pattern of the auto-calibration circuit or label 20 is shown in FIG. 5. It is contemplated that other patterns of the auto-calibration circuit or label may be formed.

Typically, at least one of the outer contact areas 88 and the inner contact area 86 will always be electrically connected to the first common connection (e.g., inner ring 52) and the second common connection (e.g., outer ring 54). For example, as shown in FIGS. 4 and 5, outer contact area 88a is always electrically connected to the outer ring 54. Similarly, inner contact area 86a is always electrically connected to the inner ring 52. By having individual outer contact areas 88 and the inner contact areas 86 only connected to the inner or outer ring 52, 54 assists in maintaining a reliable instrument since any “no connect” may be sensed by the instrument software. Thus, a defective auto-calibration circuit or label or bad connection from the instrument may be automatically sensed by the instrument software.

The instrument may include several responses to reading the auto-calibration label. For example, responses may be include the following codes: (1) correct read, (2) misread, (3) non-read, defective code, (4) non-read, missing label, and (5) read code out-of-bounds. A correct read indicates that the instrument or meter correctly read the calibration information. A misread indicates that the instrument did not correctly read the calibration information encoded in the label. In a misread, the label passed the integrity checks. A non-read, defective code indicates that the instrument senses that a label is present (continuity between two or more auto-calibration pins), but the label code fails one or more encoding rules (label integrity checks). A non-read, missing label indicates that the instrument does not sense the presence of a label (no continuity between any of the auto-calibration pins). A read code out-of-bounds indicates that the instrument senses an auto-calibration code, but the calibration information is not valid for that instrument.

According to another embodiment, the auto-calibration circuit or label may be used with one instrument. An example of such an auto-calibration circuit or label is shown in FIG. 6. An auto-calibration circuit or label 120 includes an inner ring 152, an outer ring 154, and a plurality of electrical connections 160. It is contemplated that the inner ring or the outer ring may not be continuous. For example, the inner ring 152 is not continuous because it does not extend to form a complete circle. The outer ring 154, on the other hand, is continuous. The inner ring and the outer ring may both be continuous and in another embodiment the inner ring and the outer ring are not continuous. It is contemplated that the inner ring and outer ring may be shapes other than circular.

The plurality of electrical connections 160 includes a plurality of outer contact areas 188 (e.g., contact pads). The plurality of outer contact areas 188 is radially positioned around the circumference of the auto-calibration circuit or label 120. It is contemplated that the plurality of outer contact areas may be located in different positions that depicted in FIG. 6.

The plurality of electrical connections 160 is adapted to be utilized by the instrument to auto-calibrate. The positioning of the outer contact areas 188 permits the auto-calibration circuit or label 120 to be read by instruments or meters that are capable of contacting the plurality of outer contact areas 188. The information from the plurality of electrical connections 160 corresponds to the plurality of test sensors 22. According to one embodiment, substantially all of the plurality of outer contact areas 188 are initially electrically connected to the first common connection (e.g., inner ring 152) and the second common connection (e.g., outer ring 154). To program the auto-calibration circuit or label, substantially all of the outer contact areas 188 in this embodiment will only be connected to one of the inner or outer rings 152, 154.

FIG. 6 does not depict a specific pattern, but rather shows all of the potential connections of the plurality of outer contact areas to the first and second common connections. One example of a pattern of the auto-calibration circuit or label 120 is shown in FIG. 7. It is contemplated that other patterns of the auto-calibration circuit or label may be formed.

Typically, at least one of the outer contact areas 188 will always be electrically connected to the first common connection (e.g., inner ring 152) and the second common connection (e.g., outer ring 154). For example, as shown in FIGS. 6 and 7, outer contact area 188a is always electrically connected to the outer ring 154. By having the individual outer contact areas 188 only connected to the inner or outer ring 152, 154 assists in maintaining a reliable instrument since any “no connect” may be sensed by the instrument software. Thus, a defective auto-calibration circuit or label or bad connection from the instrument may be automatically sensed by the instrument software.

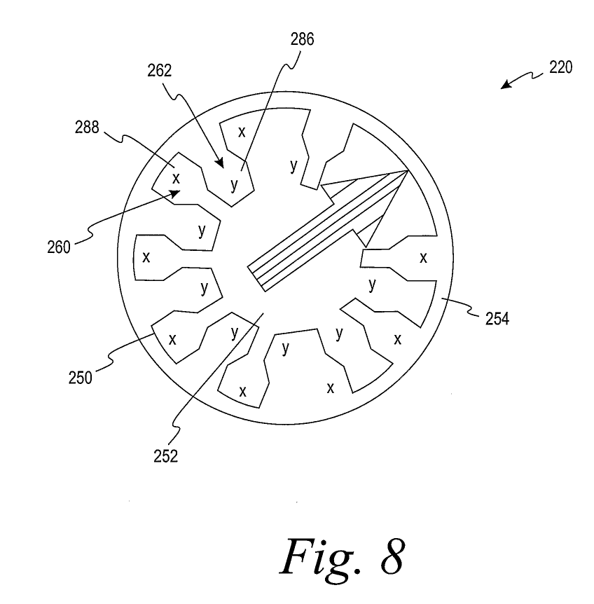

Referring to FIG. 8, an auto-calibration circuit or label 220 is depicted according to another embodiment. In this embodiment, the auto-calibration circuit or label is adapted to be used with a first instrument and a second instrument. The auto-calibration circuit or label 220 includes a first common connection 252 (e.g., a center island), a second common connection 254 (e.g., outer ring 254), a plurality of electrical connections 260, and a plurality of electrical connections 262 distinct from the plurality of electrical connections 260.

The plurality of electrical connections 260 includes a plurality of outer contact areas 288. The plurality of outer contact areas 288 is radially formed around the circumference of the auto-calibration circuit or label 220. The plurality of electrical connections 262 includes a plurality of inner contact areas 286. The inner contacts areas 286 are formed closed to the center of the label 220 than the outer contact areas 288. To better illustrate where the pins contact the respective outer and inner contact areas, FIG. 8 includes the symbols “x” (outer contact areas) and “y” (inner contact areas). It is contemplated that the plurality of outer contact areas and the inner contact areas may be located in different positions than depicted in FIG. 8.

Referring still to FIG. 8, the first common connection 252 and the second common connection 254 are produced by removing the conductive material in a line pattern 250. The line pattern 250 defines the first common connection 252 and the second common connection 254. The line pattern 250 may be produced such that any of the inner and outer contact areas 286, 288 depicted by “x” and “y”, respectively, may be joined to either the first common connection 252 or the second common connection 254.

The plurality of electrical connections 260 is adapted to be utilized by the first instrument to auto-calibrate. The plurality of electrical connections 262, on the other hand, is adapted to be utilized by the second instrument to auto-calibrate. Thus, the positioning of the outer contact areas 288 and the inner contact areas 286 permits the auto-calibration circuit or label 220 to be read by instruments or meters that are capable of contacting either the plurality of outer contacts areas 288 or the plurality of inner contacts areas 286.

The information from the plurality of electrical connections 260 corresponds to the plurality of test sensors 22. The information obtained from the plurality of electrical connections 262 also corresponds to the plurality of test sensors 22. FIG. 8 depicts one specific example of a line pattern of an auto-calibration circuit or label. It is contemplated that other line patterns of the auto-calibration label may be formed.

Typically, at least one of the outer contact areas 288 and the inner contact area 286 will always be electrically connected to the first common connection (e.g., center island 252) and the second common connection (e.g., outer ring 254). By having the individual outer contact areas 288 and the inner contact areas 286 only connected to the first common connection 252 or second common connection 254 assists in maintaining a reliable instrument since any “no connect” may be sensed by the instrument software. Thus, a defective auto-calibration circuit or label or bad connection from the instrument may be automatically sensed by the instrument software.

The auto-calibration circuit or label (e.g., auto-calibration circuits or labels 10, 120 and 220) to be used with at least one instrument may be formed according to the following method. A structure includes an electrically conductive layer is provided. A pattern is created with the electrically conductive layer using a laser to form an auto-calibration label. The pattern is created in or through the electrically conductive layer using a laser. The pattern is adapted to be utilized by the at least one instrument to auto-calibrate. For example, the auto-calibration circuit or label may be used with one instrument to auto-calibrate. More typically, the auto-calibration circuit or label is used with at least two instruments to auto-calibrate in which the first and second instruments are different.

The electrically conductive layer may include conductive metals, conductive alloys, or conductive polymeric coatings. Non-limiting examples of conductive metals and conductive alloys that may be used include aluminum, copper, nickel, palladium, silver, stainless steel, titanium nitride, platinum, gold, or combinations thereof. It is contemplated that other conductive metals may be used in forming the electrically conductive layer. The thickness of the electrically conductive metal or conductive alloy in the electrically conductive layer may vary but generally is from about 10 to about 10,000 Angstroms. More typically, the electrically conductive layer is from about 100 to about 2,500 Angstroms.

Conductive polymeric coatings are defined herein as including at least one polymeric resin and conductive particles or flakes. It is contemplated that several types of polymeric materials may be used such as, for example, thermoplastics and thermosets. Non-limiting examples of conductive particles that may be used in the conductive polymeric coatings include aluminum, carbon, graphite, copper, nickel, palladium, silver, platinum, gold, or combinations thereof. It is contemplated that other conductive particles may be used in forming the electrically conductive polymeric coatings. The thickness of the electrically conductive polymeric coatings may vary but generally is from about 0.5 micron to about 500 microns. More typically, the thickness of the electrically conductive polymeric coatings is from about 5 to about 50 microns.

The conductive polymer coatings may be formed by a variety of methods. In one method, the conductive polymer coating is formed by screen printing. In another method, the conductive polymer coating is formed by gravure printing. In a further method, the conductive polymer coating is produced onto the polymer substrate by a variety of standard coating techniques such as, for example, reverse roll, Meyer rod, doctor blade, slot die, direct gravure, offset gravure, reverse gravure, differential speed offset gravure, nip and pan feed, knife-over roll or spray coating.

In one embodiment, the structure consists of the electrically conductive layer such as, for example, a single layer of aluminum or nickel.

In another embodiment, the structure includes a polymeric portion (e.g., polymeric film) and a metallic portion. For example, the structure may be a metalized polymeric film, a coextruded metalized polymeric film, or a laminated metalized polymeric film. It is contemplated that other strictures may be employed in the methods of the present invention. The polymeric portion to be used in these structures may be formed from a variety of polymeric materials or filled-polymelic materials. The polymeric portion may have a rough or textured surface in one embodiment. The polymeric portion may have a smooth surface in another embodiment. For example, the polymeric portion may be made from materials such as polyethylene, polypropylene, oriented polypropylene (OPP), cast polypropylene (CPP), polyethylene terephthlate (PET), polyether ether ketone (PEEK), polyether sulphone (PES), polycarbonate, or combinations thereof. The thickness of the polymeric film is generally from about 6 to about 250 microns. More specifically, the thickness of the polymeric film is generally from about 25 to about 250 microns.

The metalized polymeric film may be formed by a variety of methods. In one method, the metalized polymeric film is formed by having metal sputtered on the polymeric film. In another method, the metalized polymeric film is formed by having metal vapor deposited on the polymeric film. In a further method, metal may be flashed onto the polymeric film. In another method, the metalized polymeric film may be formed by coextrusion or lamination. It is contemplated that other methods may be used in forming the metalized polymeric film to be used in the present invention.

The auto-calibration circuits or labels (e.g., auto-calibration circuits or labels 20, 120, 220) of the present invention may be formed and then attached to a sensor package (e.g., sensor package 12). The auto-calibration circuit or label may be attached to the sensor package via, for example, an adhesive or other attachment method. In another method, at least a portion of the surface of the sensor-package base includes an electrically conductive layer. The pattern is created with this electrically conductive layer using a laser. Thus, in this method the electrically conductive metal is part of the product packaging.

A laser creates the pattern with the electrically conductive layer to form an auto-calibration label. The laser functions by cutting the electrically conductive layer in selected locations to form the desired auto-calibration circuit or label. There are many different types of lasers that may be used in creating the pattern on the electrically conductive layer. The lasers to be used in the present invention remove the electrically conductive layer to isolate regions electrically.

One laser that may be used in the present invention is a solid-state laser such as a yttrium-based laser. Examples of yttrium-based lasers that are commercially available are Rofin DY-HP Series, Telesis ECLIPSE® TLM, or Telesis ZENITH® Series. It is contemplated that other yttrium-based lasers may be used.

Another type of laser that may be used in the present invention is a gas laser such as a carbon dioxide-based laser. Examples of carbon dioxide-based lasers that are commercially available are Rofin FA Series, Telesis SABRE® Series, or Keyence ML-G Series CO₂. It is contemplated that other carbon dioxide-based lasers may be used.

A further type of laser that may be used is an Excimer laser. Excimer lasers use reactive gases, such as chlorine and fluorine, that are mixed with inert gases such as argon, krypton or xenon. To obtain optimum ablation, the wavelength may need to be matched to the selected metal of the conductive layer. An example of an Excimer laser that is commercially available is Lambda Physik F₂ Series. It is contemplated that other Excimer lasers may be used. It is also contemplated that other lasers may be used in forming the auto-calibration circuits or labels of the present invention other than those discussed above in the specific examples above.

According to one method, the pattern may be created using a mask and a laser such as, for example, an Excimer laser or a carbon dioxide-based laser. Examples of patterns using a mask are shown in FIGS. 5 and 6. It is contemplated that various masks may work in conjunction with the laser in forming the auto-calibration circuit or label. One example of a mask is a chrome-on-glass mask in which the beam of light is only allowed to pass through selected areas to form the auto-calibration circuit or label.

According to one method, the pattern may be created using direct writing of the lines. In this method, the laser beam of light is moved so as to form the desired pattern. An example of an auto-calibration circuit or label formed using this method is shown in FIG. 8 with auto-calibration circuit or label 220. It is contemplated that other patterns may be created using direct writing of the lines. Lasers that produce a beam of energy capable of removing the conductive layer and that can be moved to form a pattern may be used in this method. Non-limiting examples of such lasers are carbon dioxide-based lasers and yttrium-based lasers such as yttrium aluminum garnet (YAG) lasers.

The methods of the present invention are desirable because they are adapted to work in tighter spaces. For example, the methods of the present invention can produce spaces between adjacent electrical areas of from about 1 to about 10 mils, which allows for the possibility of tighter tolerances and/or a smaller auto-calibration area.

The auto-calibration circuits or labels 20, 120 and 220 of FIGS. 4-8 are generally circular shaped. It is contemplated, however, that the auto-calibration circuits or labels may be of different shapes than depicted in FIGS. 4-8. For example, the auto-calibration circuit or label may be a square, rectangle, other polygonal shapes, and non-polygonal shapes including oval. It is also contemplated that the contacts areas may be in different locations than depicted in FIGS. 4-8. For example, the contacts may be in a linear array.

It is contemplated that the auto-calibration circuits or labels 20, 120 may be used with instruments other than instrument 10 depicted in FIGS. 1, 2. The auto-calibration circuits or labels 20, 120, 220 may also be used in other type of sensor packs than sensor package 12. For example, the auto-calibration circuits or labels may be used in sensor packages such as a cartridge with a stacked plurality of test sensors or a drum-type sensor package.

Alternative Process A

A method of forming an auto-calibration circuit or label to be used with an instrument, the method comprising the acts of:

providing a structure including an electrically conductive layer; and

creating a pattern with the electrically conductive layer using a laser to form an auto-calibration circuit or label, the pattern being adapted to be utilized by the instrument to auto-calibrate.

Alternative Process B

The method of Alternative Process A wherein the structure consists of the electrically conductive layer.

Alternative Process C

The method of Alternative Process A wherein the structure is a metalized polymeric film, a coextruded metalized polymeric film, or a laminated metalized polymeric film.

Alternative Process D

The method of Alternative Process C wherein the polymer includes polyethylene, polypropylene, oriented polypropylene (OPP), cast polypropylene (CPP), polyethylene terephthlate (PET), polyether ether ketone (PEEK), polyether sulphone (PES), polycarbonate, or combinations thereof.

Alternative Process E

The method of Alternative Process A wherein the pattern is created using a mask.

Alternative Process F

The method of Alternative Process A wherein the pattern is created using direct writing of lines.

Alternative Process G

The method of Alternative Process A wherein the electrically conductive layer includes aluminum, copper, nickel, palladium, silver, stainless steel, titanium nitride, platinum, gold, or combinations thereof.

Alternative Process H

The method of Alternative Process A wherein the thickness of the electrically conductive layer is from about 10 to about 10,000 Angstroms.

Alternative Process I

The method of Alternative Process H wherein the thickness of the electrically conductive layer is from about 100 to about 2,500 Angstroms.

Alternative Process J

The method of Alternative Process A wherein the laser is a yttrium-based laser.

Alternative Process K

The method of Alternative Process A wherein the laser is a carbon dioxide-based laser.

Alternative Process L

The method of Alternative Process A wherein the laser is an Excimer laser.

Alternative Process M

The method of Alternative Process A wherein the electrically conductive layer is an electrically conductive polymeric coating.

Alternative Process N

The method of Alternative Process M wherein the electrically conductive polymeric coating includes conductive particles comprising aluminum, carbon, graphite, copper, nickel, palladium, silver, platinum, gold, or combinations thereof.

Alternative Process O

The method of Alternative Process M wherein the electrically conductive polymeric coating has a thickness of from about 0.5 to about 500 microns.

Alternative Process P

The method of Alternative Process O wherein the electrically conductive polymeric coating has a thickness of from about 5 to about 50 microns.

Alternative Process Q

A method of forming an auto-calibration circuit or label to be used with a first instrument and a second instrument, the first instrument being different from the second instrument, the method comprising the acts of:

providing a structure including an electrically conductive layer; and

creating a pattern with the electrically conductive layer using a laser to form an auto-calibration circuit or label, the pattern being adapted to be utilized by the first instrument to auto-calibrate and being adapted to be utilized by the second instrument to auto-calibrate.

Alternative Process R

The method of Alternative Process Q wherein the pattern includes a first plurality of electrical connections being adapted to be utilized by the first instrument to auto-calibrate and a second plurality of electrical connections being adapted to be utilized by the second instrument to auto-calibrate, the second plurality of electrical connections being distinct from the first plurality of electrical connections.

Alternative Process S

The method of Alternative Process R wherein the first plurality of electrical connections includes a plurality of outer contact areas and the second plurality of electrical connections includes a plurality of inner contact areas.

Alternative Process T

The method of Alternative Process Q wherein the structure consists of the electrically conductive layer.

Alternative Process U

The method of Alternative Process Q wherein the structure is a metalized polymeric film, a coextruded metalized polymeric film, or a laminated metalized polymeric film.

Alternative Process V

The method of Alternative Process U wherein the polymer includes polyethylene, polypropylene, oriented polypropylene (OPP), cast polypropylene (CPP), polyethylene terephthlate (PET), polyether ether ketone (PEEK), polyether sulphone (PES), polycarbonate, or combinations thereof.

Alternative Process W

The method of Alternative Process Q wherein the pattern is created using a mask.

Alternative Process X

The method of Alternative Process Q wherein the pattern is created using direct writing of lines.

Alternative Process Y

The method of Alternative Process Q wherein the electrically conductive layer includes aluminum, copper, nickel, palladium, silver, stainless steel, titanium nitride, platinum, gold, or combinations thereof.

Alternative Process Z

The method of Alternative Process Q wherein the thickness of the electrically conductive layer is from about 10 to about 10,000 Angstroms.

Alternative Process AA

The method of Alternative Process Z wherein the thickness of the electrically conductive layer is from about 100 to about 2,500 Angstroms.

Alternative Process BB

The method of Alternative Process Q wherein the laser is a yttrium-based laser.

Alternative Process CC

The method of Alternative Process Q wherein the laser is a carbon dioxide-based laser.

Alternative Process DD

The method of Alternative Process Q wherein the laser is an Excimer laser.

Alternative Process EE

The method of Alternative Process Q wherein the electrically conductive layer is an electrically conductive polymeric coating.

Alternative Process FF

The method of Alternative Process EE wherein the electrically conductive polymeric coating includes conductive particles comprising aluminum, carbon, graphite, copper, nickel, palladium, silver, platinum, gold, or combinations thereof.

Alternative Process GG

The method of Alternative Process EE wherein the electrically conductive polymeric coating has a thickness of from about 0.5 to about 500 microns.

Alternative Process HH

The method of Alternative Process GG wherein the electrically conductive polymeric coating has a thickness of from about 5 to about 50 microns.

Alternative Process II

A method of forming a sensor package adapted to be used with at least one instrument in determining an analyte concentration in a fluid sample, the method comprising the acts of:

providing a structure including an electrically conductive layer;

creating a pattern with the electrically conductive layer using a laser to form an auto-calibration circuit or label, the pattern being adapted to be utilized by at least one instrument to auto-calibrate;

attaching the auto-calibration circuit or label to a surface of a sensor-package base; and

providing at least one test sensor being adapted to receive the fluid sample and being operable with the at least one instrument.

Alternative Process JJ

The method of Alternative Process II wherein the at least one test sensor is a plurality of sensors and further providing a pluralities of cavities containing a respective one of the pluralities of test sensors, the plurality of test cavities being arranged around the auto-calibration circuit or label.

Alternative Process KK

The method of Alternative Process II wherein the structure consists of the electrically conductive layer.

Alternative Process LL

The method of Alternative Process II wherein the structure is a metalized polymeric film, a coextruded metalized polymeric film, or a laminated metalized polymeric film.

Alternative Process MM

The method of Alternative Process II wherein the pattern is created using a mask.

Alternative Process NN

The method of Alternative Process II wherein the pattern is created using direct writing of lines.

Alternative Process OO

The method of Alternative Process II wherein the electrically conductive layer includes aluminum, copper, nickel, palladium, silver, stainless steel, titanium nitride, platinum, gold, or combinations thereof.

Alternative Process PP

The method of Alternative Process II wherein the thickness of the electrically conductive layer is from about 10 to about 10,000 Angstroms.

Alternative Process QQ

The method of Alternative Process PP wherein the thickness of the electrically conductive layer is from about 100 to about 2,500 Angstroms.

Alternative Process RR

The method of Alternative Process 11 wherein the laser is a yttrium-based laser.

Alternative Process SS

The method of Alternative Process II wherein the laser is a carbon dioxide-based laser.

Alternative Process TT

The method of Alternative Process II wherein the laser is an Excimer laser.

Alternative Process UU

The method of Alternative Process II wherein the electrically conductive layer is an electrically conductive polymeric coating.

Alternative Process VV

The method of Alternative Process UU wherein the electrically conductive polymeric coating includes conductive particles comprising aluminum, carbon, graphite, copper, nickel, palladium, silver, platinum, gold, or combinations thereof.

Alternative Process WW The method of Alternative Process UU wherein the electrically conductive polymeric coating has a thickness of from about 0.5 to about 500 microns.

Alternative Process XX

The method of Alternative Process WW wherein the electrically conductive polymeric coating has a thickness of from about 5 to about 50 microns.

Alternative Process YY

A method of forming a sensor package adapted to be used with at least one instrument in determining an analyte concentration in a fluid sample, the method comprising the acts of:

providing a sensor-package base having a surface, at least a portion of the surface of the sensor-package base including an electrically conductive layer;

creating a pattern with the electrically conductive layer using a laser to form an auto-calibration circuit or label, the pattern being adapted to be utilized by at least one instrument to auto-calibrate; and

providing at least one test sensor being adapted to receive the fluid sample and being operable with the at least one instrument.

Alternative Process ZZ

The method of Alternative Process YY wherein the at least one test sensor is a plurality of sensors and further providing a pluralities of cavities containing a respective one of the pluralities of test sensors, the plurality of test cavities being arranged around the auto-calibration circuit or label.

Alternative Process AAA

The method of Alternative Process YY wherein the pattern is created using a mask.

Alternative Process BBB

The method of Alternative Process YY wherein the pattern is created using direct writing of lines.

Alternative Process CCC

The method of Alternative Process YY wherein the electrically conductive layer includes aluminum, copper, nickel, palladium, silver, stainless steel, titanium nitride, platinum, gold, or combinations thereof.

Alternative Process DDD

The method of Alternative Process YY wherein the thickness of the electrically conductive layer is from about 10 to about 10,000 Angstroms.

Alternative Process EEE

The method of Alternative Process DDD wherein the thickness of the electrically conductive layer is from about 100 to about 2,500 Angstroms.

Alternative Process FFF

The method of Alternative Process YY wherein the laser is a yttrium-based laser.

Alternative Process GGG

The method of Alternative Process YY wherein the laser is a carbon dioxide-based laser.

Alternative Process HHH

The method of Alternative Process YY wherein the laser is an Excimer laser.

Alternative Process III

The method of Alternative Process YY wherein the electrically conductive layer is an electrically conductive polymeric coating.

Alternative Process JJJ

The method of Alternative Process III wherein the electrically conductive polymeric coating includes conductive particles comprising aluminum, carbon, graphite, copper, nickel, palladium, silver, platinum, gold, or combinations thereof.

Alternative Process KKK

The method of Alternative Process III wherein the electrically conductive polymeric coating has a thickness of from about 0.5 to about 500 microns.

Alternative Process LLL

The method of Alternative Process KKK wherein the electrically conductive polymeric coating has a thickness of from about 5 to about 50 microns.

While the present invention has been described with reference to one or more particular embodiments, those skilled in the art will recognize that many changes may be made thereto without departing from the spirit and scope of the present invention. Each of these embodiments, and obvious variations thereof, is contemplated as falling within the spirit and scope of the invention.

1. A method of forming an auto-calibration circuit or label to be used with an instrument, the method comprising the acts of:
providing a structure including an electrically conductive layer; and
creating a pattern with the electrically conductive layer using a laser to form an auto-calibration circuit or label, the pattern being adapted to be utilized by the instrument to auto-calibrate.

2. The method of claim 1, wherein the structure consists of the electrically conductive layer.

3. The method of claim l wherein the structure is a metalized polymeric film, a coextruded metalized polymeric film, or a laminated metalized polymeric film.

4. (canceled)

5. The method of claim 1, wherein the pattern is created using a mask.

6. The method of claim 1, wherein the pattern is created using direct writing of lines.

7. The method of claim 1, wherein the electrically conductive layer includes aluminum, copper, nickel, palladium, silver, stainless steel, titanium nitride, platinum, gold, or combinations thereof.

8. The method of claim 1, wherein the thickness of the electrically conductive layer is from about 10 to about 10,000 Angstroms.

9. The method of claim 8, wherein the thickness of the electrically conductive layer is from about 100 to about 2,500 Angstroms.

10.-15. (canceled)

16. The method of claim 15, wherein the electrically conductive polymeric coating has a thickness of from about 5 to about 50 microns.

17. A method of forming an auto-calibration circuit or label to be used with a first instrument and a second instrument, the first instrument being different from the second instrument, the method comprising the acts of:
providing a structure including an electrically conductive layer; and
creating a pattern with the electrically conductive layer using a laser to form an auto-calibration circuit or label, the pattern being adapted to be utilized by the first instrument to auto-calibrate and being adapted to be utilized by the second instrument to auto-calibrate.

18. The method of claim 17, wherein the pattern includes a first plurality of electrical connections being adapted to be utilized by the first instrument to auto-calibrate and a second plurality of electrical connections being adapted to be utilized by the second instrument to auto-calibrate, the second plurality of electrical connections being distinct from the first plurality of electrical connections.

19.-22. (canceled)

23. The method of claim 17, wherein the pattern is created using a mask.

24. The method of claim 17, wherein the pattern is created using direct writing of lines.

25.-33. (canceled)

34. The method of claim 33, wherein the electrically conductive polymeric coating has a thickness of from about 5 to about 50 microns.

35. A method of forming a sensor package adapted to be used with at least one instrument in determining an analyte concentration in a fluid sample, the method comprising the acts of:
providing a structure including an electrically conductive layer;
creating a pattern with the electrically conductive layer using a laser to form an auto-calibration circuit or label, the pattern being adapted to be utilized by at least one instrument to auto-calibrate;
attaching the auto-calibration circuit or label to a surface of a sensor-package base; and
providing at least one test sensor being adapted to receive the fluid sample and being operable with the at least one instrument.

36. The method of claim 35, wherein the at least one test sensor is a plurality of sensors and further providing a pluralities of cavities containing a respective one of the pluralities of test sensors, the plurality of test cavities being arranged around the auto-calibration circuit or label.

37.-50. (canceled)

51. A method of forming a sensor package adapted to be used with at least one instrument in determining an analyte concentration in a fluid sample, the method comprising the acts of:
providing a sensor-package base having a surface, at least a portion of the surface of the sensor-package base including an electrically conductive layer;
creating a pattern with the electrically conductive layer using a laser to form an auto-calibration circuit or label, the pattern being adapted to be utilized by at least one instrument to auto-calibrate; and
providing at least one test sensor being adapted to receive the fluid sample and being operable with the at least one instrument.

52. The method of claim 51, wherein the at least one test sensor is a plurality of sensors and further providing a pluralities of cavities containing a respective one of the pluralities of test sensors, the plurality of test cavities being arranged around the auto-calibration circuit or label.

53. The method of claim 51, wherein the pattern is created using a mask.

54. The method of claim 51, wherein the pattern is created using direct writing of lines.

55.-56. (canceled)

57. The method of claim 56, wherein the thickness of the electrically conductive layer is from about 100 to about 2,500 Angstroms.

58.-63. (canceled)

64. The method of claim 63, wherein the electrically conductive polymeric coating has a thickness of from about 5 to about 50 microns.
